(19) United States
(12) Patent Application Publication
(10) Pub. No.: US 2003/0222349 A1
(43) Pub. Date: Dec. 4, 2003

(54) Semiconductor device with multilayer interconnection structure

(75) Inventors: Shingo Tomohisa, Hyogo (JP); Mutsumi Tsuda, Hyogo (JP); Tetsuo Fukada, Hyogo (JP); Masakazu Taki, Hyogo (JP); Kenji Shintani, Hyogo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/283,286

(22) Filed: Oct. 30, 2002

(30) Foreign Application Priority Data
May 30, 2002 (JP) 2002-156935

(51) Int. Cl. H01L 23/48

(52) U.S. Cl. 257/758

(57) ABSTRACT

A plurality of interconnection layers arranged at the same level are connected by an anti-diffusion insulating layer in a lateral direction. Interconnection layers arranged at different levels are electrically connected through a plug portion in a vertical direction. A second interlayer film is arranged only at a region directly below the interconnection layer and connects the interconnection layer with the anti-diffusion insulating layer in the vertical direction. A hollow space or an interlayer film with a low dielectric constant of at most 2.5 is located laterally adjacent to each of the plurality of interconnection layers. Thus, a semiconductor device having a multilayer interconnection structure that can improve both the strength of the interconnection layers and the transmission speed of signals, and a method of manufacturing the semiconductor device can be obtained.

### BACKGROUND OF THE INVENTION

1. Field of the Invention

The present invention relates to a semiconductor device having a multilayer interconnection structure and a method of manufacturing the same, and more particularly, to a semiconductor device having a multilayer interconnection structure with reduced signal delay and increased speed and to a method of manufacturing the same.

2. Description of the Background Art Increase in signal transmission speed has been desired in multilayer interconnection. For that purpose, techniques of using copper for interconnection metal and of lowering dielectric constant of an interlayer film have been employed.

FIG. 31 is a plan view showing a layout of an interconnection pattern in a semiconductor device having a conventional multilayer interconnection structure. FIGS. 32 and 33 are schematic section views taken along the XXXII-XXXII line and the XXXIII-XXXIII line in FIG. 31, respectively.

Referring to FIGS. 31 to 33, a multilayer interconnection structure is formed on a semiconductor substrate 101. The multilayer interconnection structure is configured to have a plurality of interconnection layers 102 arranged in a layered manner.

An interlayer insulating film 106 is formed on semiconductor substrate 101, and a cavity 106c is formed in interlayer insulating film 106. An interconnection layer 102 made of copper (Cu) is embedded in cavity 106c, and an anti-diffusion barrier film 103 for preventing diffusion of copper is formed around interconnection layer 102. At an upper layer thereof, anti-diffusion insulating layer 104 are formed on which interlayer, insulating film 106 is further layered.

This interlayer insulating film 106, as with the one described above, also has cavity 106c formed therein. A via hole 106b is formed in interlayer insulating film 106 and anti-diffusion insulating layer 104, extending from the bottom surface of cavity 106c up to interconnection layer 102. Interconnection layer 102 made of copper is embedded in cavity 106c and via hole 106b. An anti-diffusion barrier film 103 for preventing diffusion of copper is formed around interconnection layer 102. It is noted that the portion to be embedded in cavity 106c of interconnection layer 102 will be referred to as an interconnection portion, and the portion to be embedded in via hole 106b will be referred to as a via plug portion in the present specification.

Lower interconnection layer 102 is electrically connected with upper interconnection layer 102 through the via plug portion of upper interconnection layer 102. As such, a plurality of layers, i.e. at least two layers, are arranged on top of another.

In the conventional multilayer interconnection structure, in order to reduce parasitic resistance and parasitic capacitance caused by the interconnection portion and the via plug portion, copper is used as a material for interconnection layer 102, since it has low resistance value and high reliability. Further, a silicon oxide film or an insulating material having a dielectric constant lower than that of the silicon oxide film is used as a material for interlayer insulating film 106 arranged between interconnection layers 102.

A damascene process is mainly employed when copper is used for interconnection layer 102, since it is difficult to process (dry etch) copper with good controllability of its dimension and shape.

FIGS. 34 and 35 are schematic section views for illustrating the damascene process. Referring to FIG. 34, a cavity 106a is pre-formed in interlayer insulating film 106. Referring to FIG. 35, a copper layer 102 is formed to fill in cavity 106a. Subsequently, planarization is performed by Chemical Mechanical Polishing (CMP) to form interconnection portion 102 with copper 102 only remaining in cavity 106a.

A multi-layered structure may be formed by a technique of, subsequent to the processes above, forming an interlayer insulating film with a via hole opened, filling the interlayer insulating film with copper, forming a via plug portion by CMP, and then forming an interconnection layer. In view of the manufacturing cost and alignment resulting from miniaturization, however, a manufacturing method using a dual damascene structure, not the technique above, is adopted.

FIGS. 36 to 39 are schematic section views showing the manufacturing method using the dual damascene structure in order of process steps. Referring to FIG. 36, anti-diffusion insulating layer 104 and interlayer insulating film 106 are layered over interconnection layer 102 formed underneath. A via hole 106b is formed in interlayer insulating film 106 by normal photolithography and etching techniques.

Referring to FIG. 37, a resist pattern 133 is formed on interlayer insulating film 106 by the normal photolithography technique. Interlayer insulating film 106 is etched using resist pattern 133 as a mask.

Referring to FIG. 38, the etching produces cavity 106c, which is to be filled with the interconnection portion, in interlayer insulating film 106. Thereafter, resist pattern 133 is peeled off.

Referring to FIG. 39, after anti-diffusion insulating layer 104 below via hole 106b is removed, anti-diffusion barrier film 103 is formed along the inner walls of cavity 106c and via hole 106b. Copper layer 102 is formed to fill in cavity 106c and via hole 106b, followed by CMP for planarization. This leaves copper layer 102 within cavity 106c and via hole 106b, resulting in upper interconnection layer 102 having a via plug.

Copper is more susceptible to oxidation than aluminum (Al) that had been used for the interconnection portion before copper, and atoms thereof likely diffuse in a film of silicon oxide or the like. Accordingly, for the purpose of preventing copper from oxidation and diffusion, a structure in which a protection film 103 covers the entire copper portion is generally employed. That is, protection film 103 is arranged at inner walls of cavity 106c and via hole 106b that form a boundary between interconnection layer 102 and interlayer insulating film 106.

Here, a conductive anti-diffusion barrier film such as a titanium nitride film, a tantalum nitride film or the like is mainly used as protection film 103 covering interconnection layer 102 except for the upper surface thereof, in order to prevent raise in interconnection resistance due to protection film 103. As a protection film for covering the upper surface of interconnection layer 102, protection film 103a is selectively formed only on the upper surface of interconnection layer 102 as shown in FIG. 40, which complicates the process. Thus, such a structure is generally used that anti-diffusion insulating layer 104 of a silicon nitride film with insulation or SiC is provided on the entire surface as shown in FIG. 41, in place of conductive barrier film 103a described above.

It is, however, difficult to develop a material accommodating lowered dielectric constant of interlayer insulating film 106. Moreover, use of low-dielectric interlayer insulating film 106 has caused a new problem in conformity with a manufacturing process (e.g. etching) of the device.

In particular, an organic polymeric material, silicon-based inorganic polymeric material or the like is generally used as a material for low-dielectric interlayer insulating film. Such a material, however, has low mechanical strength compared to the conventional silicon oxide film, greatly deteriorating the CMP resistance and thus being susceptible to damage at removal of a photoresist by oxygen plasma.

Furthermore, when increase of the signal transmission speed is desired, a hollow interconnection structure having no interlayer insulating film, i.e., having a relative dielectric constant of 1, is considered to be the most preferable form.

As to the hollow interconnection structure, a basic structure is proposed by, for example, M. B. Anand et al., “NURA: A Feasible, Gas-Dielectric Interconnect Process,” 1996 Symposium on VLSI Technology Digest of Technical Papers, pp. 82-83, which describes a basic hollow interconnection structure in which an interlayer insulating film between interconnections is removed and the interconnections are connected by another layer.

Moreover, for improvement of mechanical strength including that at CMP, Nogami et. al. proposes in Japanese Patent Laying-Open No. 2001217312 a structure in which interconnection metal is supported by a support made of an insulating layer. In the structure disclosed therein, however, the insulating layer to be the support is arranged only at a part of the interconnection, resulting in not-so-high strength of the interconnection alone. Hence, deformation easily occurs due to the internal stress of the interconnection, which causes the interconnection to be broken or short-circuited with another interconnection by bending or the like. Moreover, the method disclosed in the publication has constraints in the depth of the interlayer insulating film and pattern formation at fabrication of the insulating layer to be the support.

In Japanese Patent Laying-Open No. 10-294316, Sasaki describes a structure in which one layer of insulating film is left in the lower interconnection layer. However, the structure described in the publication has one layer of insulating film in the lower interconnection layer, increasing the effective dielectric constant between the upper and lower interconnections when the interlayer insulating film remains at the entire lower layer, while reducing the connecting force between interconnections arranged at the same level and thus reducing the strength of the entire multilayer interconnections when the interlayer insulating film remains only at a part of the lower layer. The publication also discloses a method of etching the insulating film using an interconnection as a mask, which may deteriorate interconnection characteristics, since the interconnection to be the mask is exposed to plasma for a long time. Further, in the method of etching the interlayer insulating film using a resist mask after the interconnection being formed, when the interconnection portion is exposed from the resist mask due to alignment displacement, the interconnection characteristics may be deteriorated at the exposed portion of the interconnection, or a part that cannot be removed occurs in the portion of the interlayer insulating film to be removed.

Moreover, in Japanese Patent Laying-Open No. 11-126820, Sekiguchi discloses the structure shown in FIG. 42. Referring to FIG. 42, a multilayer interconnection structure is formed on a semiconductor substrate 201 at which transistors Tr are formed. In the multilayer interconnection structure, a plurality of interconnection layers 202 are connected in the lateral direction by a silicon oxide film 204, whereas a plurality of interconnection layers 202 are connected through a plug in the vertical direction. It is noted that each interconnection layer 202 is surrounded by a barrier metal film 103. Since the structure described in the publication has a hollow space at a region directly below an interconnection portion excluding a plug portion of interconnection layer 202, deformation easily occurs due to the internal stress of the interconnection, causing interconnection layer 202 to be broken or short-circuited with another interconnection layer 202 by bending or the like.

### SUMMARY OF THE INVENTION

One object of the present invention is to provide a semiconductor device having a multilayer interconnection structure that allows improvement in both the strength of interconnection layers and signal transmission speed.

Another object of the present invention is to provide a method of manufacturing a semiconductor device having a multilayer interconnection structure that allows improvement in both the strength of interconnection layers and signal transmission speed under few constraints, without deterioration in interconnection characteristics.

A semiconductor device with multilayer interconnection structure of the present invention includes a plurality of interconnection layers, an insulating layer and an interlayer insulating film. The plurality of interconnection layers are arranged at different levels and at a same level. The insulating layer is to connect in a lateral direction the plurality of interconnection layers arranged at the same level. Each of the plurality of interconnection layers has a plug portion, through which the interconnection layers arranged at different levels are electrically connected in a vertical direction. The interlayer insulating film is arranged only at a region directly below an interconnection layer, and connects the interconnection layer with the insulating layer. Laterally adjacent to each sidewall of the plurality of interconnection layer, at least one of a hollow space and an insulating layer with a low electric constant of 2.5 or lower is positioned.

According to the semiconductor device with multilayer interconnection structure of the present invention, the interconnection layer and the insulating layer are connected in the vertical direction by the interlayer insulating film. This can increase the strength of the interconnection layer and thus suppresses deformation due to the internal stress of interconnection, preventing the interconnection layer from being broken or short-circuited with another interconnection layer by bending or the like. Moreover, by such an interconnection layout that an interlayer insulating film is arranged below an interconnection portion that has no other interconnections at upper or lower layers over a wide range, the strength of that interconnection layer can be increased. Moreover, the hollow space allows the inside of the space to have a low dielectric constant. This can increase the speed of signals transmitted in the interconnection layers. Thus, both the strength of the interconnection layers and the transmission speed of the signals can be improved.

A method of manufacturing a semiconductor device with multilayer interconnection structure of the present invention includes the following processes.

First, a first interlayer film is formed on a first interconnection layer. An opening is formed in the first interlayer film. The opening is filled with a second interlayer film. A cavity for interconnection and a plug hole extending from the bottom surface of the cavity up to the first interconnection layer is formed within the opening at the second interlayer film. By embedding the interconnection cavity and the plug opening, a second interconnection layer electrically connected to the first interconnection layer is formed. A hollow space is formed by removing the first interlayer film around the second interconnection layer and the second interlayer film.

According to the method of manufacturing a semiconductor device with multilevel interconnection structure of the present invention, only the first interlayer film is removed while the second interlayer film remains, so that the second interconnection layer can be supported from below by the second interlayer film. This can increase the strength of the second interconnection layer and thus suppress deformation due to the internal stress of interconnection, preventing the second interconnection layer from being broken or short-circuited with another interconnection layer by bending of the second interconnection layer. Moreover, by such an interconnection layout that the second interlayer film is also arranged below an interconnection portion that has no other interconnections at upper or lower layers over a wide range, the strength of that interconnection layer can be increased. Furthermore, forming of the hollow space allows the space to have a low dielectric constant. Thus, the speed of signals transmitted in interconnection layers can be increased. This enables improvement in both the strength of the interconnection layers and signal transmission speed.

Further, the second interlayer film to be a support is embedded in the hole penetrating through the first interlayer film. The hole only needs to penetrate through the first interlayer film, and therefore has few constraints in its depth and pattern formation.

The second interlayer film and the second interconnection layer are formed in the hole at the first interlayer film, so that the first interlayer film and the second interconnection layer can be formed with the same flat pattern. This eliminates the step of etching the second interlayer film using the second interconnection layer as a mask, preventing the second interconnection layer to be the mask from being exposed to plasma for a long time, thereby causing no deterioration of the interconnection characteristics. In addition, there is no need to etch the second interlayer film using a resist mask after the second interconnection layer is formed, preventing deterioration of the interconnection characteristics caused by exposure of the interconnection portion due to alignment displacement, and occurrence of an unremoved portion in the interlayer film between interconnections.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a section view schematically showing a structure of a semiconductor device having a multilayer interconnection structure according to the first embodiment of the present invention;

FIGS. 2 to 12 are schematic section views showing a method of manufacturing the semiconductor device having the multilayer interconnection structure according to the first embodiment of the present invention, in order of process steps;

FIGS. 13 and 14 are schematic section views showing a method of forming an opening in an anti-diffusion insulating layer at every layer, in order of process steps;

FIG. 15 is a schematic section view showing the anti-diffusion insulating layer with an opening formed at every layer;

FIG. 16 is a schematic section view showing the anti-diffusion insulating layer with an opening formed at every other layer;

FIGS. 17 to 19 are schematic section views showing a method of manufacturing a semiconductor device having a multilayer interconnection structure according to the second embodiment of the present invention, in order of process steps;

FIGS. 20 and 21 are schematic section views showing a method of manufacturing a semiconductor device having a multilayer interconnection structure according to the third embodiment of the present invention, in order of process steps;

FIGS. 22 to 24 are schematic section views showing a method of manufacturing a semiconductor device having a multilayer interconnection structure according to the fourth embodiment of the present invention, in order of process steps;

FIGS. 25 to 27 are schematic section views showing a method of manufacturing a semiconductor device having a multilayer interconnection structure according to the fifth embodiment of the present invention in order of process steps;

FIGS. 28 and 29 are schematic section views showing a method of manufacturing a semiconductor device having a multilayer interconnection structure according to the seventh embodiment of the present invention, in order of process steps;

FIG. 30 is a schematic section view showing a method of manufacturing a semiconductor device having a multilayer interconnection structure according to the eighth embodiment of the present invention;

FIG. 31 is a plan view showing a layout of an interconnection pattern of the semiconductor device having the conventional multilayer interconnection structure;

FIG. 32 is a schematic section view taken along the XXXII-XXXII line in FIG. 31;

FIG. 33 is a schematic section view taken along the XXXIII-XXXIII line in FIG. 31;

FIGS. 34 and 35 are schematic section views showing processes, for illustrating the damascene process;

FIGS. 36 to 39 are schematic section views showing the manufacturing method using the dual damascene structure, in order of process steps;

FIG. 40 is a schematic section view showing a protection film formed on an upper surface of an interconnection layer;

FIG. 41 is a schematic section view showing a protection film formed on an upper surface of an interconnection layer; and

FIG. 42 is a section view schematically showing the configuration of a semiconductor device having the multilayer interconnection structure disclosed in Japanese Patent Laying-Open No. 11-126820.

### DESCRIPTION OF THE PREFERRED EMBODIMENTS

Embodiments of the present invention will be described below with reference to the drawings.

First Embodiment

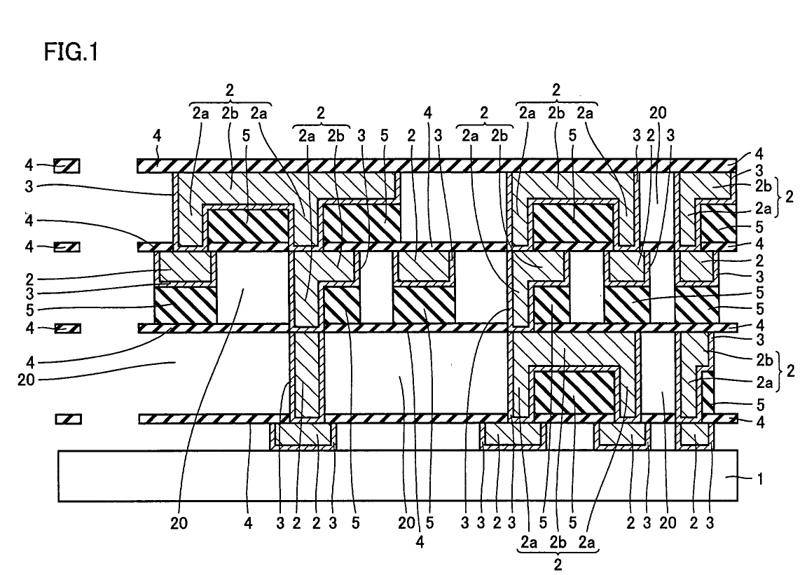

Referring to FIG. 1, in the present embodiment, a hollow interconnection structure is provided that is obtained by removing an interlayer film with only an interlayer insulating film for supporting interconnection remaining as an interlayer film in a dual damascene structure.

Specifically, a multilayer interconnection structure constituted by a plurality of interconnection layers 2 arranged at different levels and at the same level are formed on a semiconductor substrate 1 made of e.g. silicon. Each of plurality of interconnection layers 2 is made of e.g. copper, the sidewall surfaces and the bottom wall surface thereof being covered with a diffusion barrier layer 3.

The plurality of interconnection layers 2 arranged at the same level are connected in a lateral direction by an anti-diffusion insulating layer 4 that abuts an upper surface of interconnection layer 2. Each of interconnection layers 2 from the second layer above, i.e. excluding the first interconnection layer 2 that abuts semiconductor substrate 1, has a plug portion 2a and an interconnection portion 2b. An upper interconnection layer 2 is electrically connected with a lower interconnection layer 2 in the vertical direction through plug portion 2a.

A second interlayer film 5 is located only at a region directly below interconnection portion 2b in each of interconnection layers 2 from the second layer above. Second interlayer film 5 connects in the vertical direction diffusion barrier layer 3 directly below each interconnection layer 2 with anti-diffusion insulating layer 4 positioned below diffusion barrier layer 3 to support interconnection layer 2 from below. A hollow space 20 is positioned laterally adjacent to each sidewall of the plurality of interconnection layers 2.

A sidewall surface of each of interconnection layers 2 in the second layer above substantially forms a plane continuous from a sidewall surface of the second interlayer insulating film positioned directly below that interconnection layer 2. It is noted that, when diffusion barrier layer 3 is formed at the sidewall surfaces and bottom wall surface of interconnection layer 2, the “sidewall surface of interconnection layer 2” indicated above also includes a sidewall surface of diffusion layer 3, not only interconnection layer 2. That is, the sidewall surface of diffusion barrier layer 3 and that of the second interlayer insulating film form a substantially continuous plane.

A manufacturing method according to the present embodiment will now be described. In the description of the method, an arbitrary one layer in the multilayer interconnection structure is addressed, assuming that a metal interconnection (using copper here) portion formed by a similar method is provided underneath the selected layer.

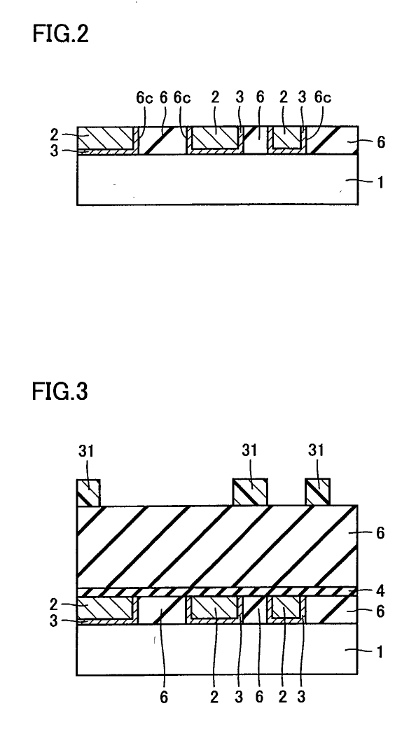

Referring to FIG. 2, an interlayer film 6 having a cavity 6c is formed on semiconductor substrate 1. Interconnection layer 2 made of copper is formed within cavity 6c. It is noted that anti-diffusion barrier film 3 is formed at the side and bottom walls of interconnection layer 2 to prevent diffusion of copper. Though tantalum nitride or the like is often used as anti-diffusion barrier film 3, any film-forming method and any material that can prevent diffusion of copper into the interlayer film may be used.

Referring to FIG. 3, anti-diffusion insulating layer 4 is formed on interconnection layer 2 and interlayer film 6 by CVD (Chemical Vapor Deposition). Anti-diffusion insulating layer 4 is formed in order to prevent oxidation and diffusion of copper. Though anti-diffusion insulating layer 4 is often made of a material such as SiN, SiC and the like, any type and forming method of the insulating film may be used that can prevent oxidation and diffusion of copper.

A first interlayer film 6 formed of a silicon oxide film doped with impurities such as boron and phosphorus (BPSG: Boron-doped PhosphoSilicate Glass) is deposited by CVD or the like on anti-diffusion insulating layer 4. Thereafter, a resist pattern 31 is formed on first interlayer film 6 by a normal photolithography technique. First interlayer film 6 is e.g. dry etched using resist pattern 31 as a mask. Subsequently, resist pattern 31 is peeled off.

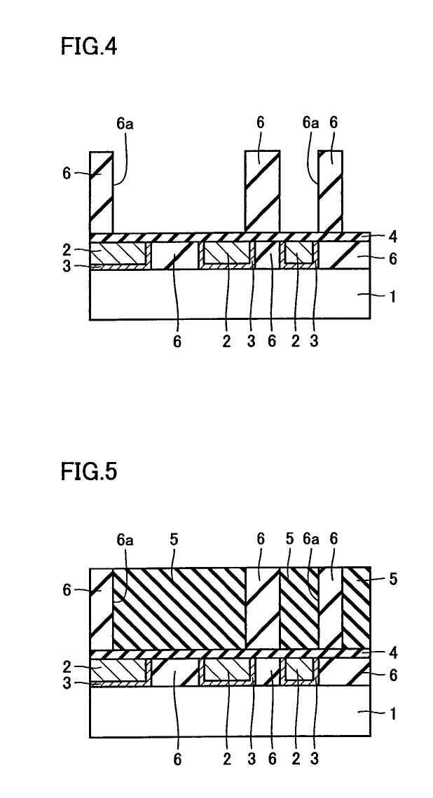

Referring to FIG. 4, the etching above isotropically processes first interlayer film 6, forming a hole 6a.

Referring to FIG. 5, second interlayer film 5 formed of a non-doped silicon oxide film is deposited in hole 6a by CVD or the like. Thereafter, the upper surfaces of second interlayer film 5 and first interlayer film 6 are planarized by CMP or the like. Here, first interlayer film 6 and second interlayer film 5 may separately be planarized. For planarization, dry etching or the like may also be used. This leaves second interlayer film 5 only in hole 6a.

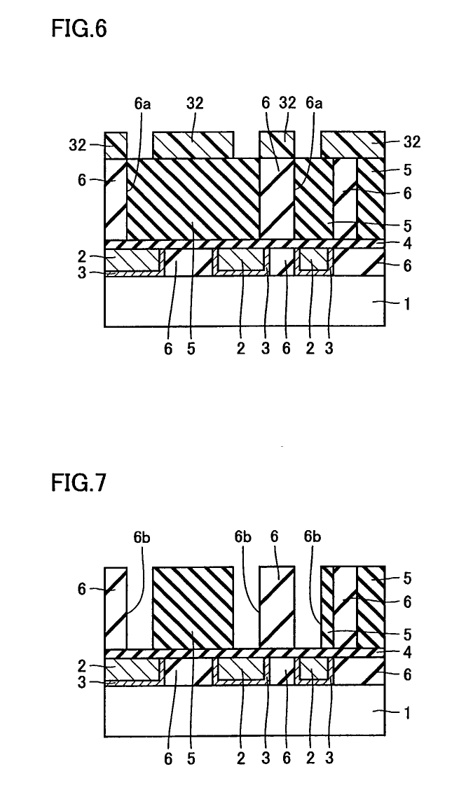

Referring to FIG. 6, a resist pattern 32 is formed on first and second interlayer films 5 and 6 by a normal photolithography technique. Second interlayer film 5 within hole 6a is e.g. dry etched using resist pattern 32 as a mask. At the dry etching, anti-diffusion insulating layer 4 serves as an etching stopper. Subsequently, resist pattern 32 is peeled off.

Referring to FIG. 7, the etching above isotropically processes second interlayer film 6, forming a via hole 6b that reaches the surface of anti-diffusion insulating layer 4.

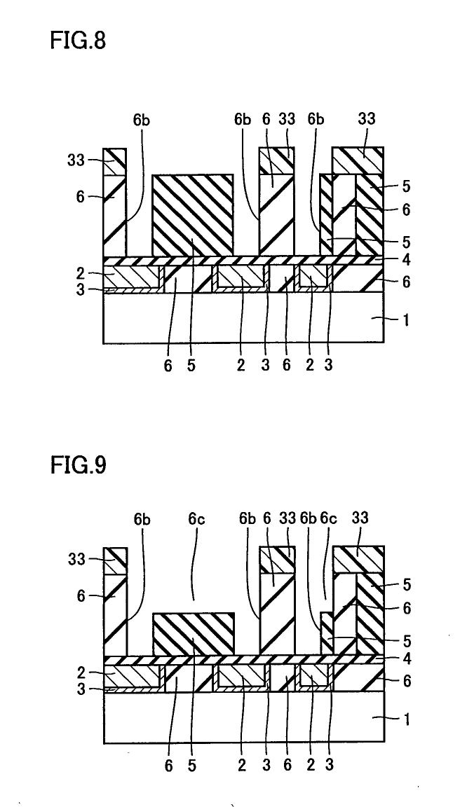

Referring to FIG. 8, a resist pattern 33 is formed on first and second interlayer films 5, 6 by the normal photolithography technique. Second interlayer film 5 is e.g. dry etched using resist pattern 33 as a mask.

Referring to FIG. 9, the etching above removes second interlayer film 5 by a prescribed amount, forming cavity 6c. Thereafter, resist pattern 33 is peeled off. Anti-diffusion insulating layer 4 located at the bottom of via hole 6b is then removed by etching so as to form via hole 6b that reaches lower interconnection layer 2.

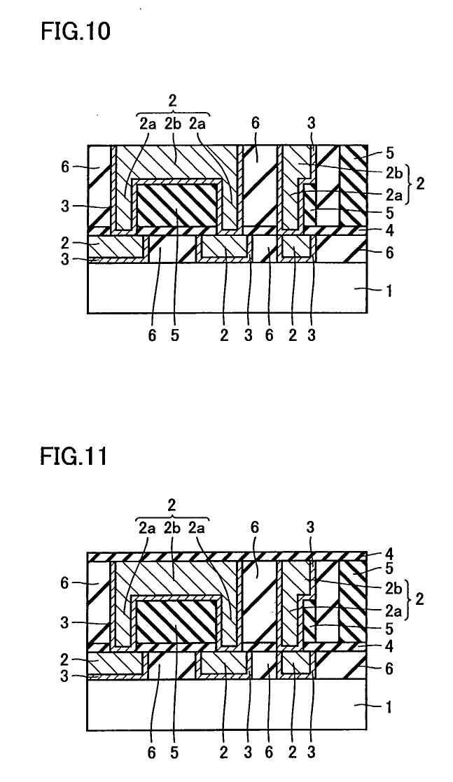

Referring to FIG. 10, anti-diffusion barrier film 3 and interconnection metal layer 2 are formed in via hole 6b and cavity 6c, and planarized by CMP or the like. This leaves interconnection metal layer 2 only within via hole 6b and cavity 6c, forming interconnection layer 2 having plug portion 2a and interconnection portion 2b.

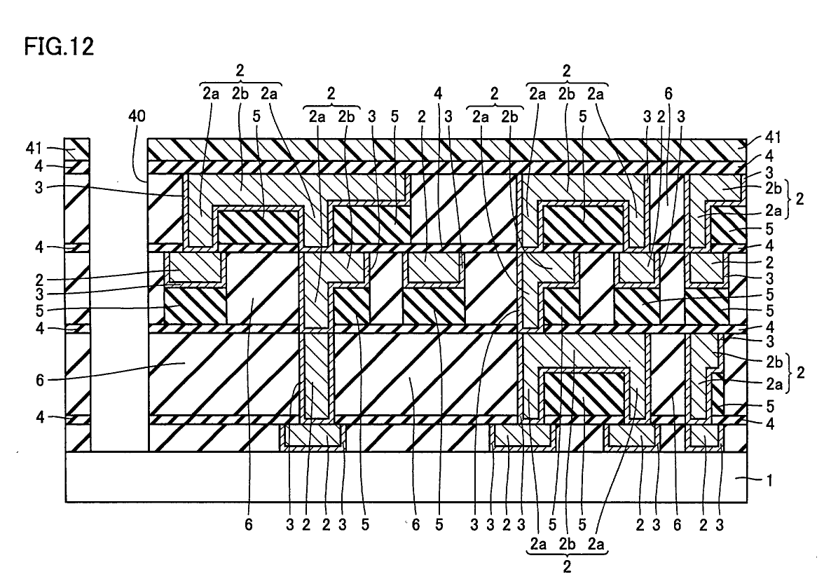

Referring to FIG. 11, anti-diffusion insulating layer 4 is formed on the entire surface for preventing oxidation and diffusion of interconnection layer 2, so that one layer of interconnection is formed among the multilayer interconnection structure. It is noted that anti-diffusion insulating layer 4 serves as an etching stopper at forming of an upper interconnection layer. By repeating the processes described above, a multilayer interconnection structure having a desired number of interconnections is formed as shown in FIG. 12.

Referring to FIG. 12, a resist pattern 41 having an opening pattern is subsequently formed at the top layer. The multi-layered interconnections are etched from the top to bottom layers, using resist pattern 41 as a mask. This produces an opening 40, not overlapping with the interconnections. Through opening 40, first interlayer film 6 in each layer is removed. Thus, the multilayer interconnection structure with hollow interconnections as shown in FIG. 1 can be manufactured.

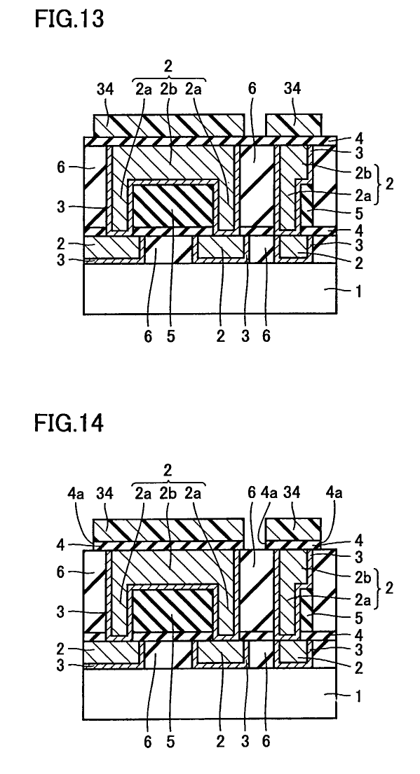

It is noted that an opening 4a may be formed at anti-diffusion insulating layer 4 in each layer, after anti-diffusion insulating layer 4 is formed, as shown in FIGS. 13 and 14. Opening 4a is formed, as shown in FIG. 14, by etching anti-diffusion layer 4 using resist pattern 34 formed as shown in FIG. 13 as a mask.

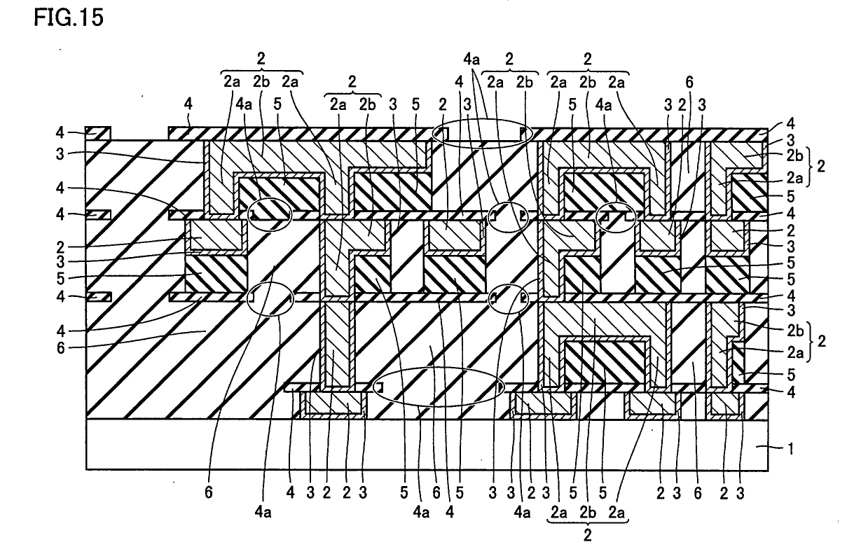

Opening 4a thus formed each at various portions of anti-diffusion insulating layer 4 as shown in FIG. 15 facilitates etchant to spread over different portions through opening 4a at removal of first interlayer film 6 in each layer. This allows shorter time and improved removability in the step of removing first interlayer film 6.

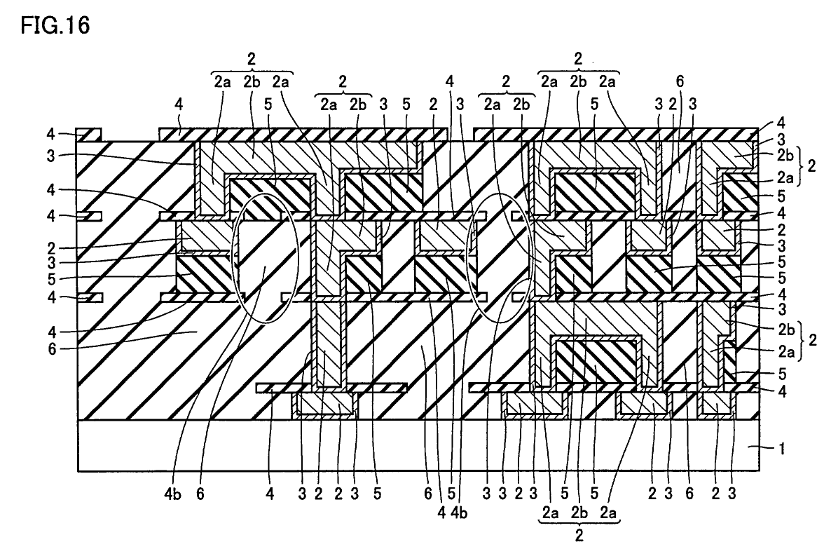

Further, while opening 4a is provided at every anti-diffusion insulating layer 4 in FIGS. 13 to 15, such an opening may appropriately be formed at every other layer or every three layers so as to facilitate the process. FIG. 16 shows an example in which an opening 4b is provided in anti-diffusion insulating layer 4 at every other layer. Here, a larger number of openings may be formed compared to the examples in FIGS. 13 to 15, and the number of process steps as well as cost can be reduced compared to when opening 4a is formed at every layer.

In the description above, BPSG was used for first interlayer film 6 and a non-doped silicon oxide film was used for second interlayer film 5, any combination of the materials for the first and second interlayer films 6, 5 may be possible that prevents second interlayer film 5 from easily being removed in the step of removing first interlayer film 6.

In the step of removing first interlayer film 6, however, it is required for first interlayer film 6 to be made of a material that can easily be removed while anti-diffusion insulating layer 4 is of a material that cannot easily be removed. To prevent difficulty in planarization of first interlayer film 6 and second interlayer film 5 by CMP in the process shown in FIGS. 4 and 5, first interlayer film 6 may preferably be of a material that can attain a polishing characteristic similar to that of second interlayer film 5 for CMP. With respect to the etching process required in the step of forming a dual damascene shape shown in the processes of FIGS. 6 to 9, first interlayer film 6 may desirably attain an etching characteristic similar to that of second interlayer film 5.

Accordingly, a doped silicon oxide film may be used for first interlayer film 6, whereas a silicon oxide film formed by CVD or a non-doped silicon oxide film such as TEOS (Tetra Ethyle Ortho Silicate) formed by CVD may be used for second interlayer film 5, facilitating establishment of the process in each step.

When the doped silicon oxide film is used for first interlayer film 6 as described above, etching by hydrofluoric acid (HF) in vapor phase may be adopted to remove first interlayer film 6, facilitating establishment of the process in each step as described earlier.

Second Embodiment

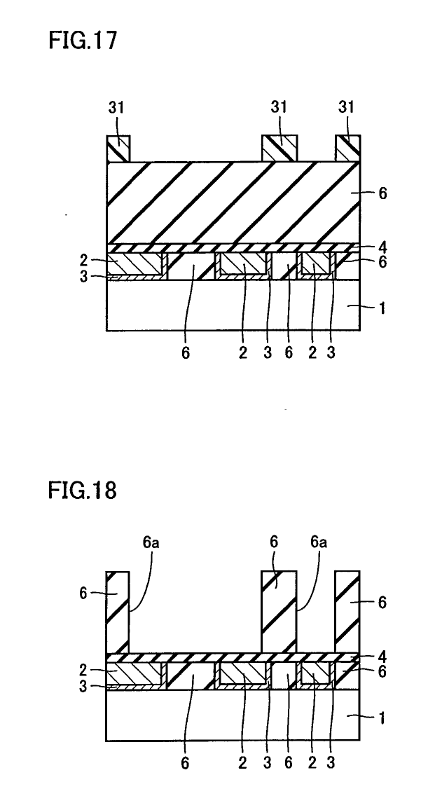

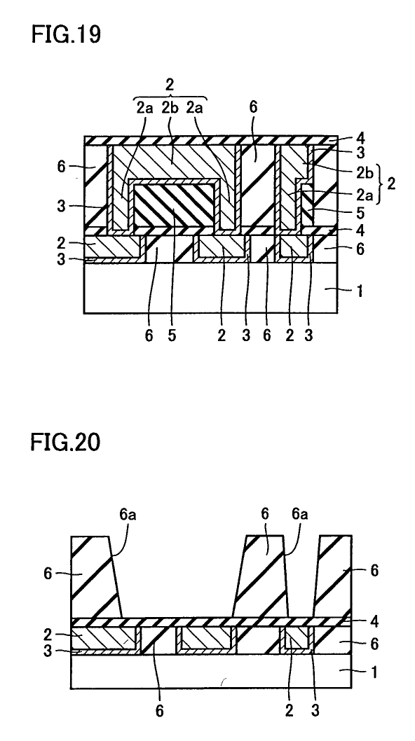

Referring to FIG. 17, in the present embodiment, the flat pattern shape of resist pattern 31 shown in FIG. 3 in the first embodiment is assumed to be the same as the flat pattern shape of resist pattern 33 shown in FIG. 8. First interlayer film 6 is etched using resist pattern 31 as a mask to form a hole 6a having a shape shown in FIG. 18, and the subsequent processes similar to those in the first embodiment are performed to form interconnection layer 2 as shown in FIG. 19.

It is noted that the other manufacturing processes are approximately the same as the processes described above in the first embodiment, so that the description thereof will not be repeated.

In the present embodiment, the flat pattern shape of resist pattern 31 shown in FIG. 3 in the first embodiment is made the same as that of resist pattern 33 shown in FIG. 8, so that both resist patterns 31 and 33 can be formed using the same photomask (reticle). Thus, the number of photomasks in the photolithography technique can be reduced while second interlayer film 5 is arranged along the lower side of interconnection layer 2, allowing increase in strength.

Third Embodiment

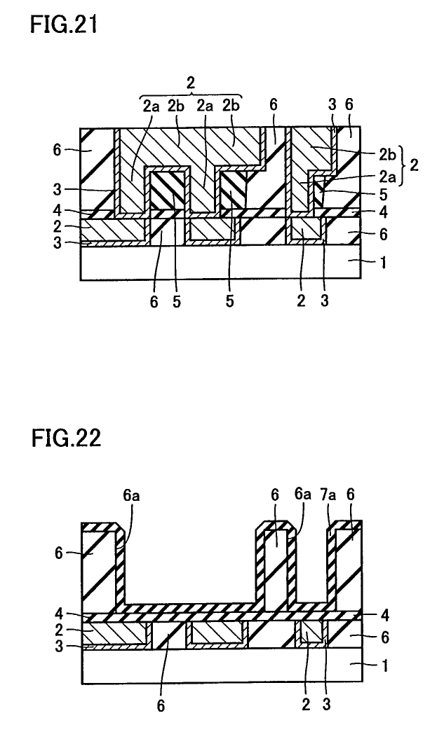

The manufacturing method according to the present embodiment first goes through the process steps shown in FIGS. 2 and 17. Subsequently, a hole 6a is formed to have a tapered shape with the opening dimension reduced toward the lower side as shown in FIG. 20. Thereafter, the subsequent processes similar to those in the first embodiment are performed to form interconnection layer 2 as shown in FIG. 21.

It is noted that the other manufacturing processes are approximately the same as the processes described above in conjunction with the first and second embodiments, so that the description thereof will not be repeated.

In the present embodiment, hole 6a has a tapered shape, allowing the width of second interlayer film 5 supporting interconnection layer 2 to be thinner than that of interconnection layer 2, so that the capacitance between the upper and lower interconnections can be reduced.

Fourth Embodiment

The manufacturing method according to the present embodiment first goes through the processes shown in FIGS. 2, 17 and 18. Subsequently, a third interlayer film 7a is formed with a relatively small thickness as shown in FIG. 22. Third interlayer film 7a is formed of a material having an etching rate approximately equal to that of first interlayer film 6 in the step of removing first interlayer film 6. Examples of such material are BPSG, which is the same as the material for first interlayer film 6, and PSG doped with phosphorus only. Thereafter, etch back is performed on the entire surface until the surface of first interlayer film 6 is exposed.

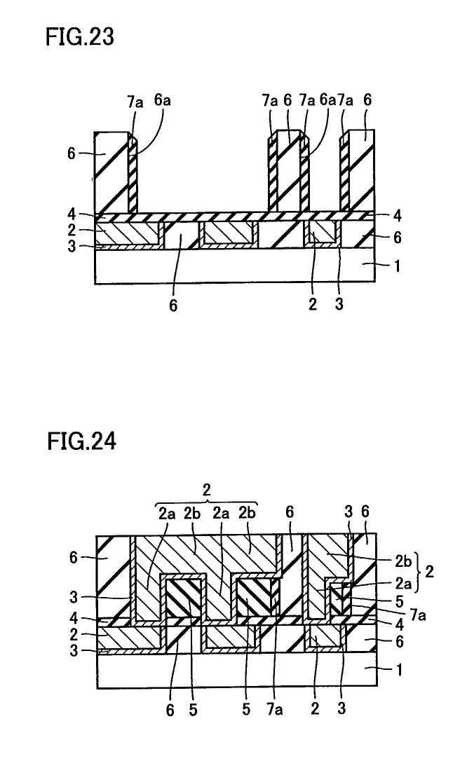

Referring to FIG. 23, the etch back leaves third interlayer film 7a at the sidewalls of hole 6a as a sidewall-shaped insulating layer. Thereafter, the subsequent processes similar to those in the first embodiment are performed to form interconnection layer 2 shown in FIG. 24.

Note that the other manufacturing processes are approximately the same as those in the first and second embodiments described earlier, so that the description thereof will not be repeated.

In the present embodiment, sidewall-shaped insulating layer 7a is formed at the sidewalls of hole 6a, allowing the width of second interlayer film 5 supporting interconnection layer 2 to be thinner than that of interconnection layer 2, so that the capacitance between the upper and lower interconnections can be reduced.

Moreover, third interlayer film 7a is formed of a material with an etching rate approximately equal to that of first interlayer film 6, allowing third interlayer film 7a to be removed simultaneously with the removal of first interlayer film 6.

Fifth Embodiment

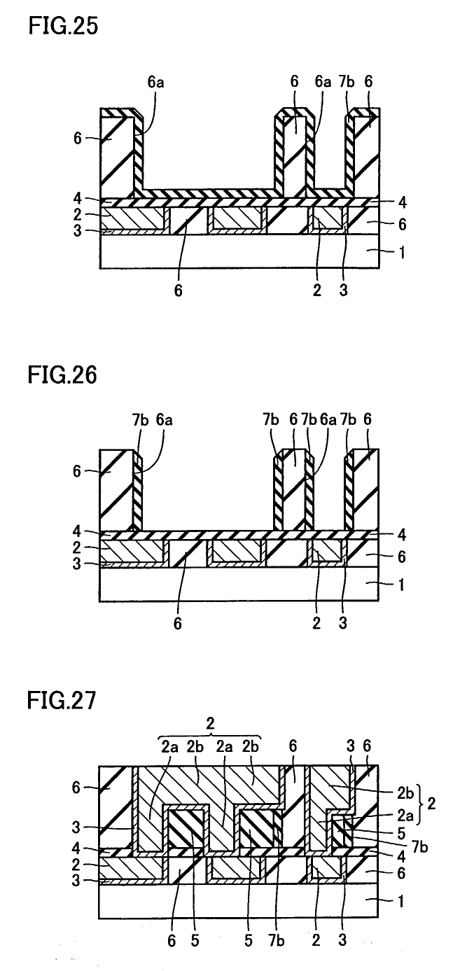

The manufacturing method according to the present embodiment first goes through the processes shown in FIGS. 2, 17 and 18. Subsequently, a third interlayer film 7b is formed with a relatively small thickness as shown in FIG. 25. Third interlayer film 7b is formed of a material which is etched very little, i.e. which has a small etching rate, at etching of first interlayer film 6, for example, of a silicon nitride film or the like. Thereafter, etch back is performed on the entire surface until the surface of first interlayer film 6 is exposed.

Referring to FIG. 26, the etch back leaves third interlayer film 7b at the sidewalls of hole 6a as a sidewall-shaped insulating layer. Thereafter, the subsequent processes similar to those in the first embodiment are performed to form interconnection layer 2 shown in FIG. 27.

It is noted that the other manufacturing processes are approximately the same as those in the first and second embodiments described earlier, so that the description thereof will not be repeated.

In the present embodiment, second interlayer film 5 is protected by third interlayer film 7a at the step of removing first interlayer film 6 to form a hollow space. This eliminates the need for forming second interlayer film 5 with a material that is not easily removed at removing of first interlayer film 6, allowing a material with good embedding and planarizing property to be selected. This may facilitate the step of forming interlayer films.

In addition, more options for the material for second interlayer film 5 are available, since there is no need to consider the etching selectivity of first interlayer film 6 and second interlayer film 5. For example, the same BPSG as that for first interlayer film 6 may also be used for second interlayer film 5.

Here, when hydrofluoric acid (HF) gas in vapor phase is used in the step of removing first interlayer film 6, BPSG, a silicon oxide film and a silicon nitride film are used for first interlayer film 6, second interlayer film 5 and third interlayer film 7b, respectively. Third interlayer film 7b may, however, be any material that has an etching rate smaller than that of interlayer film 6 in the step of removing first interlayer film 6, and may be a silicon oxide film that is the same as the material for second interlayer film 5.

Sixth Embodiment

Though an insulating material was used for first interlayer film 6 in the first to fifth embodiments, first interlayer film 6 may also be a conductive material such as e.g. aluminum.

This allows the CMP characteristic such as the mechanical strength of first interlayer film 6 and interconnection layer 2 to be closer to each other in planarzing of interconnection layer 2, shown in FIG. 10, allowing the effect of preventing remainder and scratch at CMP.

Furthermore, the conductivity allows plating even if a seed layer that is required for copper plating has a low coating property, improving applicability to miniaturization.

Seventh Embodiment

By using materials with different etching properties, e.g. siliconoxide-based (such as TEOS) and organic-based materials for second interlayer film 5 and first interlayer film 6 respectively, a mask for via etching may be formed to have a large size to perform etching as in self alignment. Even if patterns for forming interconnections are displaced from one another, etching can also be performed as in self alignment. This allows margin to be provided for alignment displacement.

A number of combinations of materials for first interlayer film 6 and second interlayer film 5 are possible in the method above. When an organic-based interlayer film with a low dielectric constant is used as first interlayer film 6 whereas a silicon oxide-based film (SiO₂, TEOS, BPTEOS or the like) is used as second interlayer film 5, CF-based plasma or the like such as C₄F₈ may be used in etching for forming a dual damascene structure to etch only second interlayer film 5 without first interlayer film 6 etched, and oxygen plasma may be used in removal of first interlayer film 6, i.e. the last process.

On the contrary, when a silicon oxide-based material is used for first interlayer film 6 whereas an organic interlayer film with a low dielectric constant is used for second interlayer film 5, mechanical strength in the CMP process may be improved. Thus, plasma such as O₂, N₂, H₂ or the like may be used in etching for forming the dual damascene structure, to etch only second interlayer film 5 without first interlayer film 6 etched. At removal of first interlayer film 6 performed at last, hydrofluoric acid-based aqueous solution may be used.

An example will be described in which a silicon oxide film is used for first interlayer film 6 whereas an organic-based interlayer film with low dielectric constant is used for second interlayer film 5.

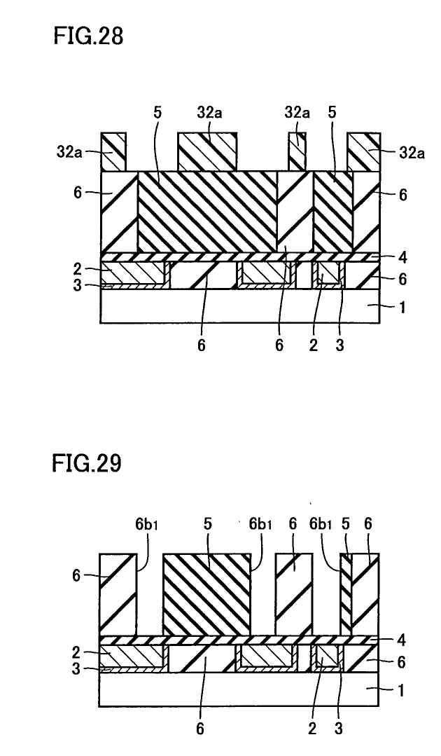

The processes similar to those described in the first embodiment with reference to FIGS. 2 to 5 are performed until second interlayer film 5 is formed and planarized by CMP or the like. If the combination of the interlayer films as indicated above is adopted in the subsequent resist patterning for a via hole, oxygen or hydrogen may be used to etch second interlayer film 5 to form a via hole. This hardly etches first interlayer film 6. Resist pattern 32 in the first embodiment described with reference to FIG. 6 may be formed to have a large opening pattern as in resist pattern 32a shown in FIG. 28.

Use of resist pattern 32a having such a large opening pattern is advantageous in that the portion to be opened as via hole 6b₁ as shown in FIG. 29 will not be smaller than a required size, and that a margin for alignment displacement will be increased.

When another combination of the materials for first interlayer film 6 and second interlayer film 5 such as an organic-based film and a silicon oxide-based film, respectively, are used, second interlayer film 5 may be etched using fluorocarbon-based plasma, with first interlayer film 6 hardly etched.

Eighth Embodiment

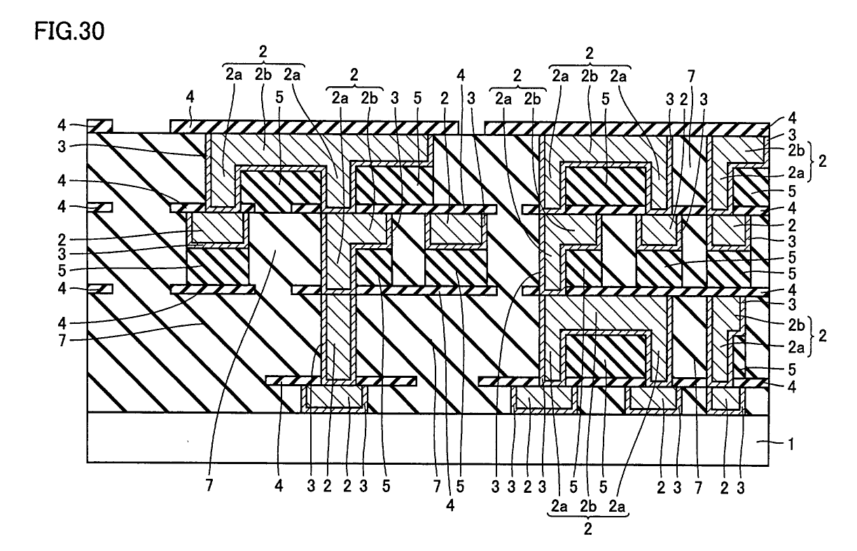

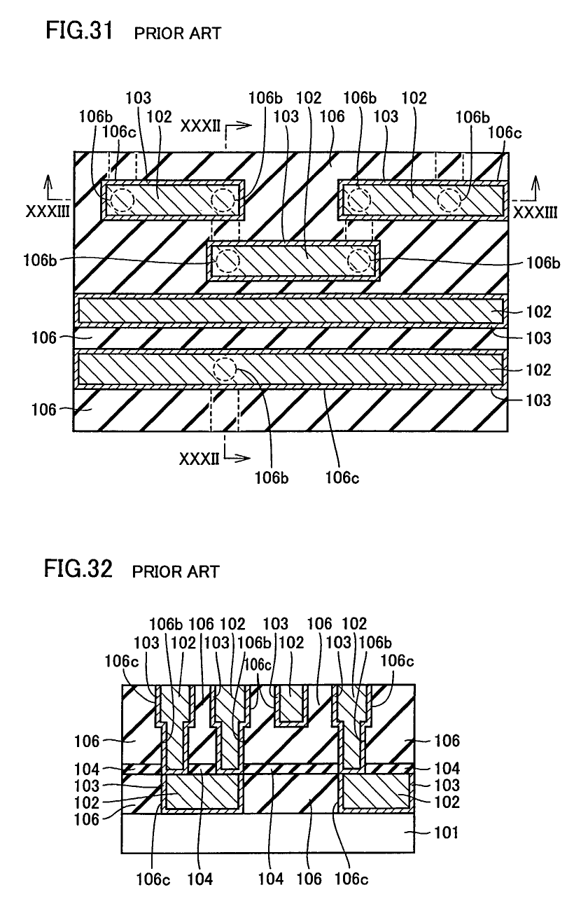

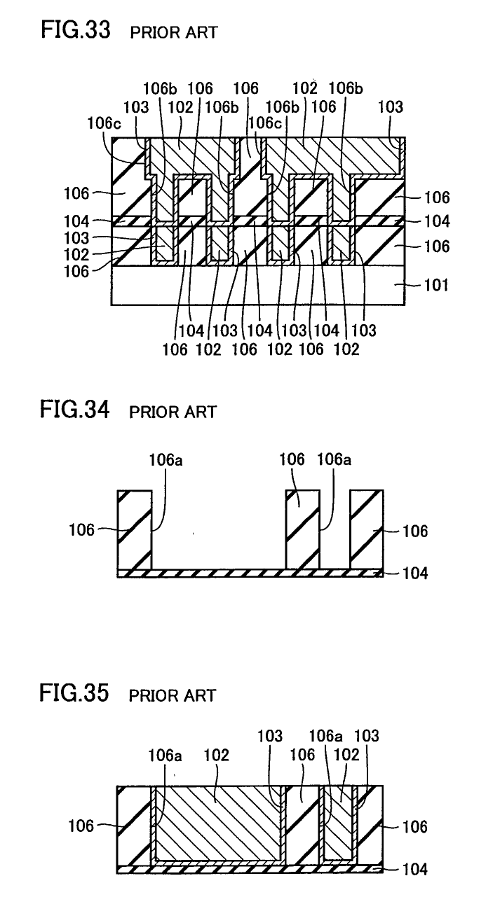

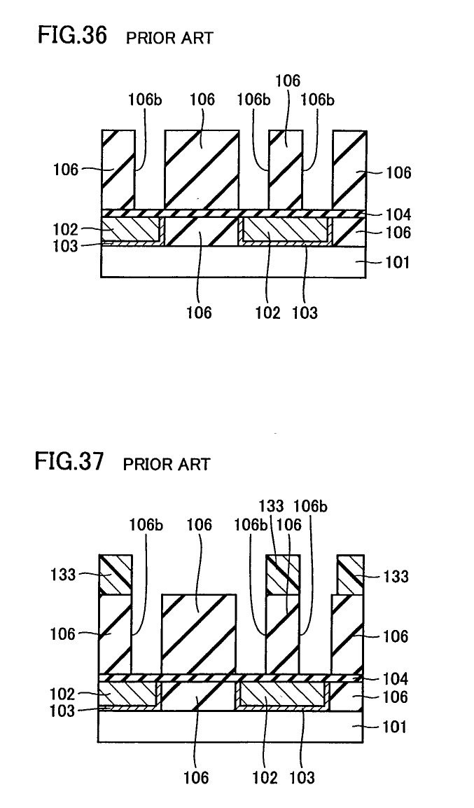

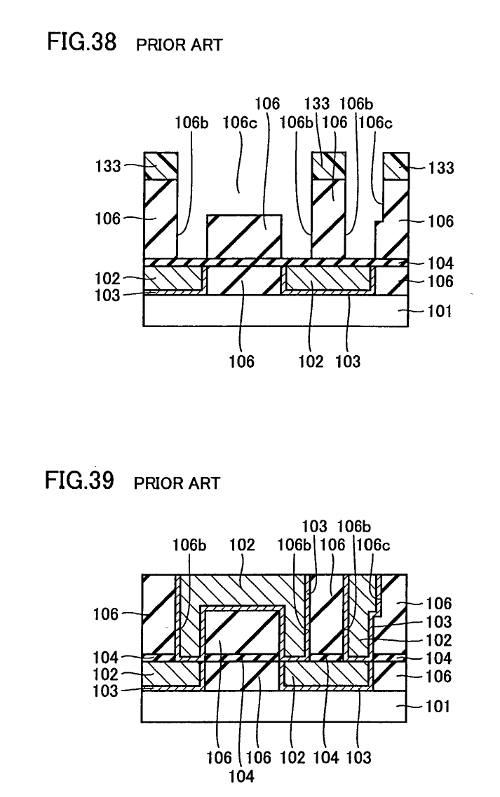

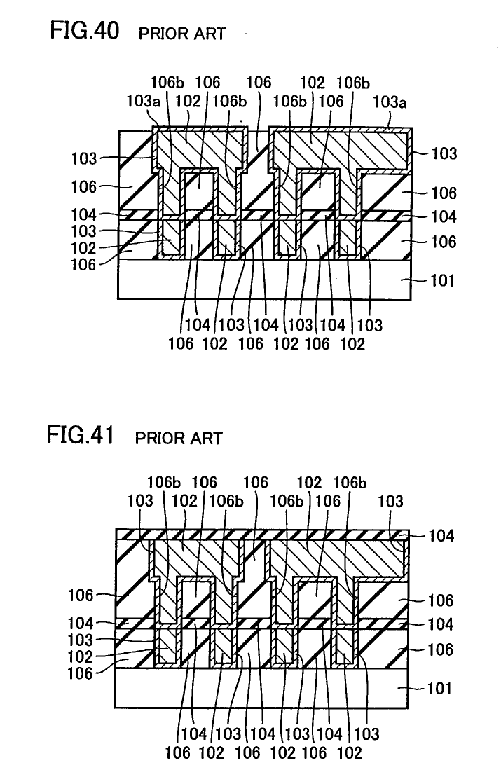

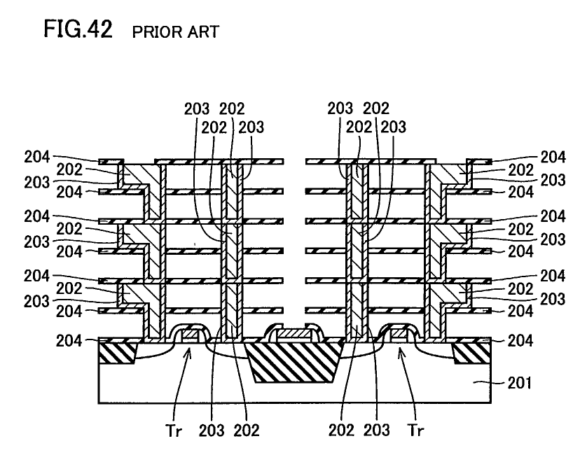

After fabricating the hollow structure as shown in FIG. 1, a fourth interlayer film 7 may be formed as a new interlayer film with a low dielectric constant as shown in FIG. 30, to fabricate a structure using an interlayer film which is difficult to be processed or which has low mechanical strength. This technique increases the strength of the entire semiconductor device, allowing improvement in reliability of the entire device.

It is noted that fourth interlayer film 7 has a dielectric constant of 2.5 or lower. Moreover, CVD or a whirling technique by spin coating may be used to form fourth interlayer film 7. Fourth interlayer film may be formed of e.g. an SiOC film when the CVD technique is used, and of polyarylether when the whirling technique by spin coating is used.

In the present embodiment, it is unnecessary to embed fourth interlayer film 7 in all the spaces laterally adjacent to interconnection layer 2, and a hollow space may remain in part.

Furthermore, as described in the first embodiment, when first interlayer film 6 is removed at every layer or every other layer, fourth interlayer film 7 may be formed after removal of first interlayer film 6, in which planarization may be performed after fourth interlayer film 7 is formed.

In the semiconductor device with multilayer interconnection structure, a sidewall surface of an interlayer insulating film preferably forms a plane substantially continuous from a sidewall surface of an interconnection layer located directly above the interlayer insulating film. Thus, the lower side of the interconnection layer can entirely be supported by the interlayer insulating film, further preventing the interconnection layer from being broken or short-circuited with another interconnection layer by bending.

In the semiconductor device with multilayer interconnection structure, the interlayer insulating film preferably has a width smaller than the width of the interconnection layer located directly above the interlayer insulating film. By thus making the width of the interlayer insulating film smaller than the width of the interconnection portion, the effective dielectric constant between the upper and lower interconnections can be lowered.

In the semiconductor device with multilayer interconnection structure, the interlayer insulating film preferably has a first interlayer insulating film and a second interlayer insulating film covering the side surfaces of the first interlayer insulating film, the first and second interlayer insulating films being made of different materials. This can extend the range of choices of a material for the second interlayer film, i.e., a material with good embedding property can be selected as a material for the second interlayer film.

In the method of manufacturing a semiconductor device with multilayer interconnection structure, preferably, the flat pattern of the photoresist used as a mask at forming of the hole has the same shape of that used as a mask at forming of the cavity for interconnection. This allows the photomask (reticle) used at forming of the photoresist used as a mask at forming of the hole to have the same pattern as that used at forming of the photoresist used as a mask at forming of the cavity for interconnection. Thus, the same photomask may be used to form both the photoresist at forming of the hole and the photoresist at forming of the cavity for interconnection. This can reduce the number of photomasks for patterning.

In the method of manufacturing a semiconductor device with multilayer interconnection structure, the hole is preferably formed to have a tapered shape with decreasing opening dimension as it goes toward the lower side of the first interlayer film. Thus, the amount of the second interlayer film to be embedded in the hole can be reduced, allowing reduction of the effective dielectric constant between the upper and lower interconnections.

In the method of manufacturing a semiconductor device with multilayer interconnection structure, after the hole is formed, a third interlayer film is preferably formed covering the upper surface of the first interlayer film and the inner wall surfaces of the hole. By etching the third interlayer film until the upper surface of the first interlayer film and the bottom surface of the hole are exposed, a sidewall layer is formed with the third interlayer film remaining only at the sidewall surfaces of the hole. The second interlayer film is formed to be embedded in the hole in which the sidewall layer is formed at the sidewall surfaces. The sidewall layer remains without being removed in the step of removing the first interlayer film. Such a sidewall layer allows the interlayer film to function as an etching stopper layer when the first interlayer film is removed by etching. This eliminates the need for the second interlayer film to serve as an etching stopper layer) extending the range of choices of a material for the second interlayer film, such that a material with good embedding property can be selected as a material for the second interlayer film.

In the method of manufacturing a semiconductor device with multilayer interconnection structure, after the hole is formed, a third interlayer film is preferably formed covering the upper surface of the first interlayer film and the inner wall surfaces of the hole. By etching the third interlayer film until the upper surface of the first interlayer film and the bottom surface of the hole are exposed, a sidewall layer is formed with the third interlayer film remaining only at the sidewall surfaces of the hole. The second interlayer film is formed to be embedded in the hole in which the sidewall layer is formed at the sidewall surfaces. The sidewall layer is also removed in the step of removing the first interlayer film, to expose the sidewalls of the second interlayer film. This can reduce the amount of the second interlayer film, allowing further reduction of the capacitance between interconnections.

In the method of manufacturing a semiconductor device with multilayer interconnection structure, preferably, the first interlayer film is a silicon oxide film which impurity is doped whereas the second interlayer film is a silicon oxide film which impurity is not doped. Such selection of the materials easily ensures etching selectivity of the first and second interlayer films.

In the method of manufacturing a semiconductor device with multilayer interconnection structure, the step of removing the first interlayer film preferably uses reactive gas including at least hydrofluoric acid in vapor phase. This allows the doped silicon oxide film to favorably be etched.

In the method of manufacturing a semiconductor device with multilayer interconnection structure, the first interlayer film is preferably made of a conductive material. This can increase the mechanical strength of the first interlayer film, so that remainder and scratch can be prevented when the CMP technique is used to planarize the upper surface of the first interlayer film. This can facilitate the CMP technique as well as formation of a barrier film and an interconnection layer film.

In the method of manufacturing a semiconductor device with multilayer interconnection structure, the second interlayer film is preferably selected to have an etching rate higher than that of the first interlayer film at etching for forming a cavity for interconnection and a plug hole. By using a material different from that for the first interlayer film at forming of the insulating film for support, a self-aligned contact hole can be formed that allows etching with a desirable via diameter using a resist pattern having a via diameter larger than the desirable via diameter in via etching for making connection between interconnections. This increases a margin for alignment displacement.

In the method of manufacturing the semiconductor device with multilayer interconnection structure, a fourth interlayer film is embedded in at least a part of a hollow space formed by removing the first interlayer film. By thus forming a new interlayer film with a low dielectric constant in the structure in which the hollow space is formed, the entire device can have increased strength.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device having a multilayer interconnection structure, comprising:
a plurality of interconnection layers arranged at different levels and at a same level;
an insulating layer to connect said plurality of interconnection layers arranged at the same level in a lateral direction,
each of said plurality of interconnection layers having a plug portion, said interconnection layers arranged at different levels being electrically connected via said plug portion in a vertical direction; and
an interlayer insulating film arranged at a region directly below said interconnection layer, to connect said interconnection layer with said insulating layer,
at least one of a hollow space and an insulating layer with a low dielectric constant of at most 2.5 being located at a region laterally adjacent to a sidewall of each of said plurality of interconnection layers.

2. The semiconductor device having a multilayer interconnection structure according to claim 1, wherein said interlayer insulating film has a sidewall surface forming a plane substantially continuous from a sidewall surface of said interconnection layer located directly above said interlayer insulating film.

3. The semiconductor device having a multilayer interconnection structure according to claim 1, wherein said interlayer insulating film has a width smaller than a width of said interconnection layer located directly above said interlayer insulating film.

4. The semiconductor device having a multilayer interconnection structure according to claim 1, wherein said interlayer insulating film has a first interlayer insulating film and a second interlayer insulating film covering a side surface of said first interlayer insulating film, and
said first and second interlayer insulating films are made of different materials.

5. A method of manufacturing a semiconductor device having a multilayer interconnection structure, comprising the steps of:
forming a first interlayer film on a first interconnection layer;
forming a hole in said first interlayer film;
embedding a second interlayer film into said hole;
forming a cavity for interconnection and a plug hole extending from a bottom surface of said cavity for interconnection up to said first interconnection layer, within said hole, on said second interlayer film;
forming a second interconnection layer electrically connected to said first interconnection layer by embedding said cavity for interconnection and said plug hole; and
removing said first interlayer film around said second interconnection layer and said second interlayer film to form a hollow space.

6. The method of manufacturing a semiconductor device having a multilayer interconnection structure according to claim 5, wherein a flat pattern of a photoresist used as a mask at forming of said hole has a same shape as a flat pattern of a photoresist used as a mask at forming of said cavity for interconnection.

7. The method of manufacturing a semiconductor device having a multilayer interconnection structure according to claim 5, wherein said hole is formed to have a tapered shape with a decreasing dimension of an opening toward a lower side of said first interlayer film.

8. The method of manufacturing a semiconductor device having a multilayer interconnection structure according to claim 5, further comprising the steps of:
forming a third interlayer film covering an upper surface of said first interlayer film and an inner wall surface of said hole, after said hole is formed; and
forming a sidewall layer with said third interlayer film remaining only on a sidewall surface of said hole by etching said third interlayer film until an upper surface of said first interlayer film and a bottom surface of said hole are exposed,
said second interlayer film being formed to be embedded in said hole in which said sidewall layer is formed at a sidewall surface,
said sidewall layer remaining without being removed at the step of removing said first interlayer film.

9. The method of manufacturing a semiconductor device having a multilayer interconnection structure according to claim 5, further comprising the steps of:
forming a third interlayer film covering an upper surface of said first interlayer film and an inner wall surface of said hole after said hole is formed; and
etching said third interlayer film until an upper surface of said first interlayer film and a bottom surface of said hole are exposed, to form a sidewall layer with said third interlayer film remaining only on a sidewall surface of said hole,
said second interlayer film being formed to be embedded in said hole in which said sidewall layer is formed at a sidewall surface,
said sidewall layer being simultaneously removed in said step of removing said first interlayer film such that a sidewall of said second interlayer film is exposed.

10. The method of manufacturing a semiconductor device having a multilayer interconnection structure according to claim 5, wherein said first interlayer film is a silicon oxide film which impurity is doped, and
said second interlayer film is a silicon oxide film which impurity is not doped.

11. The method of manufacturing a semiconductor device having a multilayer interconnection structure according to claim 5, wherein the step of removing said first interlayer film uses a reactive gas including at least hydrofluoric acid in vapor phase.

12. The method of manufacturing a semiconductor device having a multilayer interconnection structure according to claim 5, wherein said first interlayer film is made of a conductive material.

13. The method of manufacturing a semiconductor device having a multilayer interconnection structure according to claim 5, wherein a material for said second interlayer film is selected to have an etching rate higher than an etching rate of said first interlayer film at etching for forming said cavity for interconnection and said plug hole.

14. The method of manufacturing a semiconductor device having a multilayer interconnection structure according to claim 5, further comprising the step of embedding a fourth interlayer film in at least a part of said hollow space formed by removing said first interlayer film.
